(19) United States
(12) Patent Application Publication
(10) Pub. No.: US 2023/0087120 A1
(43) Pub. Date: Mar. 23, 2023

(54) Method for Producing a Structured Wavelength Conversion Layer and Optoelectronic Device with a Structured Wavelength Conversion Layer

(71) Applicant: OSRAM Opto Semiconductiors GmbH, Regensburg (DE)

(72) Inventors: David O'Brien, Portland, OR (US); Erik Johansson, Portland, OR (US)

(21) Appl. No.: 17/479,190

(22) Filed: Sep. 20, 2021

(51) Int. Cl. H01L 33/50

(52) U.S. Cl. CPC H01L 33/504; B82Y 20/00

(57) ABSTRACT

In an embodiment a method for producing a structured wavelength conversion layer includes providing a first wavelength conversion layer with wavelength converting properties such that electromagnetic radiation of a first wavelength range is converted into electromagnetic radiation of a second wavelength range, structuring of the first wavelength conversion layer into first regions and second regions, wherein the wavelength converting properties of the first wavelength conversion layer are impaired or removed in the first regions after structuring.

### TECHNICAL FIELD

A method for producing a structured wavelength conversion layer and an optoelectronic device with a structured wavelength conversion layer are specified.

### SUMMARY

Embodiments provide a method for producing a structured wavelength conversion layer by using simple and efficient techniques. Further embodiments provide an optoelectronic device with a structured wavelength conversion layer which can be produced in a simple and efficient manner.

According to at least one embodiment, the method for producing a structured wavelength conversion layer comprises providing a first wavelength conversion layer with wavelength converting properties such that electromagnetic radiation of a first wavelength range is converted into electromagnetic radiation of a second wavelength range.

In other words, the first wavelength conversion layer is designed to convert electromagnetic radiation of the first wavelength range into electromagnetic radiation of the second wavelength range. In particular, the electromagnetic radiation of the second wavelength range comprises longer wavelengths than the electromagnetic radiation of the first wavelength range.

In particular, the first wavelength conversion layer is provided on a substrate, for example a semiconductor chip, preferably emitting blue light. For example, the first wavelength conversion layer is provided by spin coating, spray coating, dip coating, doctor blading or screen printing, in particular on the substrate.

According to at least one embodiment, the method further comprises structuring of the first wavelength conversion layer into first regions and second regions. In particular, the first regions and the second regions differ in their properties after the structuring. A structural integrity of the first wavelength conversion layer can be maintained during the structuring of the first wavelength conversion layer. This means that an extent of the first wavelength conversion layer is not changed during structuring. In other words, no material is removed during structuring of the first wavelength conversion layer.

According to at least one embodiment, the wavelength converting properties of the first wavelength conversion layer are impaired or removed in the first regions after the structuring. In particular, this means that in the first regions the first wavelength conversion layer an ability of the first wavelength conversion layer to convert electromagnetic radiation of the first wavelength range into electromagnetic radiation of the second wavelength range is at least reduced. Preferably, the first wavelength conversion layer is in the first regions no longer capable of converting electromagnetic radiation. In particular, the second regions remain unimpaired and thus the ability of the first wavelength conversion layer to convert electromagnetic radiation of the first wavelength range into electromagnetic radiation of the second wavelength range remains in the second regions.

According to a preferred embodiment, the method comprises structuring the first wavelength conversion layer with wavelength converting properties such that electromagnetic radiation of the first wavelength range is converted into electromagnetic radiation of the second wavelength range and structuring of the first wavelength conversion layer into first regions and second regions. Thereby, the wavelength converting properties of the wavelength conversion layer are impaired or removed in the first regions after the structuring.

Using this method, a structured wavelength conversion layer can be produced in an efficient manner. Advantageously, the structured wavelength conversion layer is still mechanically intact and planar after structuring. In contrast, commonly produced structured wavelength conversion layers show an uneven topology. For example, regions with and without the wavelength conversion layer exist, which makes it challenging to apply further layers on the wavelength conversion layer. This problem is avoided by the presently described method.

According to at least one embodiment, the first wavelength conversion layer comprises nanoparticles. In particular, nanoparticles are particles with a diameter between 1 nanometer and 100 nanometers, both inclusive. Preferably, the nanoparticles comprise wavelengths converting properties. The nanoparticles may comprise or consist of a semiconductor material.

According to at least one embodiment, the nanoparticles are quantum dots. In particular, the quantum dots are designed to convert electromagnetic radiation of the first wavelength range into electromagnetic radiation of the second wavelength range. In other words, the quantum dots can have the ability to absorb electromagnetic radiation of the first wavelength range and to emit electromagnetic radiation of the second wavelength range.

Preferably, the quantum dots are based on III-V compound semiconductor materials or II-VI compound semiconductor materials. III-V compound semiconductor materials comprise at least one element from group 3 of the periodic table, for example B, Al, Ga, In, and at least one element from group 5 of the periodic table, for example N, P, As, Sb. II-VI compound semiconductor materials comprise at least one element from group 2 or 12 of the periodic table, for example Mg, Ca, Sr, Ba, Zn, Cd, and at least one element from group 6 of the periodic table, for example O, S, Se.

Preferably, the quantum dots are based on Cd or In. For example, the quantum dots comprise or consist of CdS or InP. It is further possible, that the quantum dots are encapsulated, for example by a further semiconductor material or an insulating material, in particular SiO₂ or Al₂O₃. If the quantum dots comprise or consist of CdS, ZnS may be used as encapsulant.

The quantum dots can be provided by impregnation into pores of a semiconductor material. In particular, the quantum dots can be impregnated into porous GaN.

According to at least one embodiment, the ability of the quantum dots to absorb electromagnetic radiation of the first wavelength range is impaired or removed in the first regions after the structuring of the wavelength conversion layer. In other words, at least a part of the quantum dots stop absorbing electromagnetic radiation of the first wavelength range. In particular, at least a part of the quantum dots become transparent in the first regions after the structuring of the first wavelength conversion layer. Preferably, all quantum dots in the first wavelength conversion layer lose their ability to absorb electromagnetic radiation of the first wavelength range.

Furthermore, it is possible that the quantum dots do not scatter electromagnetic radiation in the first regions after the structuring of the first wavelength conversion layer.

According to at least one embodiment, a composition, in particular a chemical composition, of the first wavelength conversion layer is changed in the first regions during structuring of the first wavelength conversion layer. In particular, the chemical composition of the nanoparticles, especially the quantum dots, in the first wavelength conversion layer is changed in the first regions during structuring of the first wavelength conversion layer. For instance, the first wavelength conversion layer can be bleached in the first regions.

Due to the changed composition of the first wavelength conversion layer in the first regions, the wavelength conversion properties of the first wavelength conversion layer are impaired or removed in the first regions after the structuring. In particular, the first wavelength conversion layer gets transparent for electromagnetic radiation of the first wavelength range in the first regions because of the changed composition of the first wavelength conversion layer in the first regions.

According to at least one embodiment, the composition, in particular the chemical composition, of the first wavelength conversion layer is changed in the first regions by oxidation processes during structuring of the first wavelength conversion layer. In particular, an oxidation is defined as a loss of electrons from one of the components of the nanoparticle. In other words, an oxidation state is increased. In the oxidation process an oxidizing agent can be used to change the composition of the first wavelength conversion layer in the first regions. The oxidizing agent has preferably an ability to accept electrons, in particular of the nanoparticles, especially of the quantum dots, in the first wavelength conversion layer.

According to at least one embodiment, the semiconductor material of the nanoparticles, especially the quantum dots, is oxidized during structuring of the first wavelength conversion layer. In particular, the elements of group 5 or group 6 in the III-V compound semiconductor material or the II-VI compound semiconductor material, respectively, are oxidized. Preferably, the semiconductor material is converted to the corresponding oxides, hydroxides and/or oxyanions of the elements of group 5 or group 6. For example, the oxyanion can be sulfate (SO₄_{^{2−}}) or phosphate (PO₄³⁻).

For example, if the first wavelength conversion layer comprises CdS quantum dots encapsulated with ZnS, O₂ in the presence of water and UV radiation can be used as oxidizing agent and thus can be used to change the chemical composition of the first conversion layer in the first regions. The oxidation process occurring can be described by the following unbalanced chemical equation:

MS+H₂O+O₂->M_{x/2+y}(OH)ₓ(SO₄), where M=Cd(II) and/or Zn(II).

If quantum dots based on InP are used in the first wavelength conversion layer, the semiconductor material InP can be converted to InPO₄ and other related oxo and hydroxy species.

According to at least one embodiment, a protective mask is applied on the first wavelength conversion layer during structuring of the first wavelength conversion layer and the protective mask is patterned to generate the first regions and the second regions. A patterning of the protective mask can be performed by photolithography. It is also possible that the protective mask is applied in a patterned matter to generate the first regions and the second regions. This means that the protective mask is not applied on the whole surface of the first wavelength conversion layer but only in some locations. Such an applying of the protective mask can be performed, for example, by printing or transfer techniques.

In particular, the first regions are free of the protective mask, whereas the second regions are covered by the protective mask. Such a design of the protective mask enables that the composition of the first wavelength conversion layer can be changed selectively only in the first regions. In other words, the protective mask prevents the change of the composition of the first wavelength conversion layer in the second regions.

Preferably, the protective mask has an ability to protect the first wavelength conversion layer in the second regions from moisture and/or electromagnetic radiation. In other words, the protective mask can act as moisture barrier.

According to at least one embodiment, the protective mask is removed after the composition of the first wavelength conversion layer is changed in the first regions.

According to at least one embodiment, the first regions are treated with UV radiation during the structuring of the first wavelength conversion layer. It can also be possible to use blue light to treat the first regions during structuring of the first wavelength conversion layer. By treating the first regions with UV radiation or blue light it is possible to use less reactive reagents to change the composition of the first wavelength conversion layer in the first regions. In this way, it can be prevented that possible layers beneath the first wavelength conversion layer are damaged.

According to at least one embodiment, the first wavelength conversion layer is heated during structuring. For example, the first wavelength conversion layer is heated to a temperature of at most 150° C., at most 100° C., at most 85° C., or at most 50° C.

According to at least one embodiment, the first regions are treated with at least one of O₂, O₃, H₂O₂, or N₂O during structuring of the first wavelength conversion layer. In particular, these substances are used to change the composition of the first wavelength conversion layer in the first regions. O₂, O₃, H₂O₂, and N₂O can have an ability to accept electrons. In other words, O₂, O₃, H₂O₂, and N₂O are oxidizing agents.

If the more reactive gases O₃ or N₂O are used to treat the first regions, it is possible to omit treating the first regions with UV radiation during the structuring of the first wavelength conversion layer. In this case, the oxidizing properties are strong enough to change the composition of the first wavelength conversion layer without an additional treatment with UV radiation.

For example, dissolved O₂ is used to treat the first regions during structuring of the first wavelength conversion layer. O₂ is for example dissolved in water or an alcohol. Trace amounts of basic water can serve to balance the chemical reaction.

According to at least one embodiment, aqueous redox chemistry is performed in the first regions during the structuring of the first wavelength conversion layer. In particular, the aqueous redox chemistry is performed to change the composition of the first wavelength conversion layer in the first regions. “Aqueous” means in this context, that water is present during the redox reaction.

Preferably, sulfate (SO₄²⁻) is present during performing the aqueous redox chemistry. This prevents dissolution of CdSO₄, if quantum dots comprising CdS are present in the first wavelength conversion layer.

According to at least one embodiment, non-aqueous redox chemistry is performed in the first regions during the structuring of the first wavelength conversion layer. In particular, the non-aqueous redox chemistry is performed to change the composition of the first wavelength conversion layer in the first regions. “Non-aqueous” means in this context, that no water is present during the redox reaction.

Advantageously, by using non-aqueous redox chemistry, the dissolution of CdSO₄ is prevented, in the case that quantum dots comprising CdS are present in the first wavelength conversion layer. Also, other compounds generated during changing the composition of the first wavelength layer in the first regions are preferably not dissolved using non-aqueous redox chemistry. The structure of the first wavelength conversion layer can thus be maintained.

According to at least one embodiment, the first wavelength conversion layer is electrically biased during structuring the first wavelength conversion layer. Advantageously, it is possible to reduce the amount of UV radiation, reduce a time for applying the oxidizing agents, and/or use milder oxidizing agents during structuring of the first wavelength conversion layer.

All conditions presently described avoid the use of aggressive etching of the wavelength conversion layer. This at least reduces chemical damage to the wavelength conversion layer. In particular, rough edges, under-etching, and delamination are prevented.

According to at least one embodiment, moisture is removed from the first wavelength conversion layer. In particular, this can be necessary if during the structuring of the first wavelength conversion layer water has been present. Preferably, the moisture is removed from the first wavelength conversion layer if aqueous redox chemistry is performed during the structuring of the first wavelength conversion layer. For example, the moisture is removed by heating or under reduced pressure.

According to at least one embodiment, a protective layer is applied on the first wavelength conversion layer after structuring of the first wavelength conversion layer. The protective layer can protect the underlying first wavelength conversion layer from degradation, for example by moisture and/or air. In particular, the protective layer acts as a barrier for moisture. For example, the protective layer covers side surfaces of the first wavelength conversion layer.

Preferably, the protective layer is formed by atomic layer deposition (ALD), chemical vapor deposition (CVD), plasma-enhanced chemical vapor deposition (PECVD), metal-organic chemical vapor deposition (MOCVD), or a sol-gel process.

Preferably, the protective layer comprises or consists of SiO₂, Al₂O₃ or TiO₂ alone or in combination. It is also possible that the protective layer is a layer stack of different materials. For example, the layer stack comprises alternating layers of Al₂O₃, TiO₂ and/or SiO₂.

The protective layer can have a thickness between 50 nanometers and 500 nanometers, both inclusive, preferably between 50 nanometers and 200 nanometers, both inclusive, particularly preferably between 50 nanometers and 100 nanometers, both inclusive.

According to at least one embodiment, the protective layer penetrates into the first wavelength conversion layer, in particular in the first and/or the second regions. This can be the case if the protective layer is deposited by ALD, in particular if the protective layer comprises an insulating material such as Al₂O₃. If the protective layer penetrates into the first wavelength conversion layer, it is possible that the first wavelength conversion layer comprises quantum dots without an encapsulation.

According to at least one embodiment, the method further comprises providing a second wavelength conversion layer on the first wavelength conversion layer and structuring of the second wavelength conversion layer into third regions and fourth regions. The second wavelength conversion layer has wavelength converting properties such that electromagnetic radiation of the first wavelength range is converted into electromagnetic radiation of a third wavelength range. Preferably, the first, the second and the third wavelength range comprise at least partly different wavelengths.

All features described in combination with the first wavelength conversion layer and its structuring are also applicable to the second wavelength conversion layer. In this regard, the first regions are equal to the third regions and the second regions are equal to the fourth regions.

In particular, the first wavelength conversion layer and the second wavelength conversion layer differ in their composition. Preferably, the first wavelength conversion layer and the second wavelength conversion layer comprise or consist of different nanoparticles, in particular different quantum dots. In this regards, the quantum dots may differ in their size or composition. For example, the first wavelength conversion layer can comprise quantum dots based on Cd, whereas the second wavelength conversion layer can comprise quantum dots based on In, or vice versa. Alternatively, the first wavelength conversion layer and the second wavelength conversion layer comprise quantum dots based on the same semiconductor material, but having different sizes.

According to at least one embodiment, a protective layer is applied on the second wavelength conversion layer after structuring of the second wavelength conversion layer. All features and advantages described in combination with the protective layer on the first wavelength conversion layer also apply to the protective layer on the second wavelength conversion layer. The protective layer on the second wavelength conversion layer can cover the side surfaces of the second wavelength conversion layer. The protective layer on the second wavelength conversion layer can penetrate into the second wavelength conversion layer.

According to at least one embodiment, at least one additional layer is applied on the first and/or the second wavelength conversion layer. In particular, the additional layer is applied on the protective layer on the first and/or second wavelength conversion layer. Advantageously, the additional layer can enhance the mechanical stability of the wavelength conversion layers.

Further, an optoelectronic device is specified. Preferably, the optoelectronic device comprises a wavelength conversion layer produced by the method described herein. Features and embodiments disclosed in conjunction with the method are thus also disclosed for the optoelectronic device and vice versa.

According to at least one embodiment, the optoelectronic device comprises a light-emitting semiconductor chip and a first wavelength conversion layer with wavelength converting properties such that electromagnetic radiation of a first wavelength range is converted into electromagnetic radiation of a second wavelength range. The first wavelength conversion layer comprises first regions and second regions, wherein the wavelength converting properties of the first wavelength conversion layer are impaired or removed in the first regions.

In particular, the light-emitting semiconductor chip emits electromagnetic radiation of the first wavelength range through a radiation exit surface. It is furthermore possible, that the light-emitting semiconductor chip is comprised of individual emission regions that can be driven independently from one another. For example, a lateral extension of one emission region is between 5 micrometers and 150 micrometers, both inclusive, preferably between 5 micrometers and 50 micrometers, both inclusive, particularly preferably between 5 micrometers and 10 micrometers, both inclusive. The lower limit of the lateral extension of one emission region can also be 1 micrometer.

The first wavelength conversion layer can be arranged on the radiation exit surface of the light-emitting semiconductor chip. Preferably, the first wavelength conversion layer is a continuous layer. In other words, there are no gaps or other discontinuities in the first wavelength conversion layer. In particular, the first wavelength conversion layer has a thickness of less than 20 micrometers, preferably less than 15 micrometers, particularly preferably less than 10 micrometers, for example less than 5 micrometers.

According to at least one embodiment, the first regions and the second regions have the same size. Alternatively, the first regions and the second regions can have a different size. In this regard, it is possible that the first regions are smaller than the second regions or vice versa. Preferably, the size of the first regions and the second regions is smaller than the size of the emission regions. In particular, a lateral extent of the first region and/or the second region is between 5 micrometers and 150 micrometers, both inclusive, preferably between 5 micrometers and 50 micrometers, both inclusive, particularly preferably between 5 micrometers and 10 micrometers, both inclusive. The lateral extent of the first region and/or the second region can also be less than 5 micrometers.

In particular, the first regions and the second regions have in plan view the shape of a trapezoid, preferably a parallelogram, particularly preferably a rectangle, a triangle or a hexagon.

According to at least one embodiment, the first wavelength conversion layer comprises nanoparticles, preferably quantum dots. In particular, the nanoparticles or quantum dots can convert electromagnetic radiation of the first wavelength range to electromagnetic radiation of the second wavelength range. This means that, the nanoparticles or quantum dots are the reason for the wavelength converting properties of the first wavelength conversion layer.

By using quantum dots in the first wavelength conversion layer, a high absorption of the electromagnetic radiation of the first wavelength range can be achieved, even using a thin first wavelength conversion layer.

According at least one embodiment, the first wavelength range is between 430 nanometers and 490 nanometers, both inclusive, and the second wavelength range is between 600 nanometers and 800 nanometers, both inclusive. In other words, the first wavelength range can be the blue wavelength range of the visible electromagnetic radiation and the second wavelength range can be the red wavelength range of the visible electromagnetic radiation.

According to at least one embodiment, a protective layer is arranged on the side of the first wavelength conversion layer facing away from the light-emitting semiconductor chip. The protective layer prevents a degradation of the first wavelength conversion layer, for example by moisture. A thickness of the protective layer may be between 20 nanometers and 200 nanometers, both inclusive. Alternatively, the thickness of the protective layer can be up to 10 micrometers, preferably up to 5 micrometers.

According to at least one embodiment, the optoelectronic device further comprises as second wavelength conversion layer with wavelength converting properties such that electromagnetic radiation of the first wavelength range is converted into electromagnetic radiation of a third wavelength range. Preferably, the second wavelength conversion layer is a continuous layer. The third wavelength range can be between 490 nanometers and 570 nanometers, both inclusive. In other words, the third wavelength range can be the green wavelength range of the visible electromagnetic radiation. In particular, the second wavelength conversion layer has a thickness of less than 20 micrometers, preferably less than 15 micrometers, particularly preferably less than 10 micrometers, for example less than 5 micrometers.

Preferably, the second wavelength conversion layer is arranged on the side of the first wavelength conversion layer facing away from the light-emitting semiconductor chip. The second wavelength conversion layer can be arranged on the protective layer. A side surface of the first wavelength conversion layer can be covered or passivated by the protective layer.

According to at least one embodiment, the second wavelength conversion layer comprises third and fourth regions. The wavelength converting properties of the second wavelength conversion layer can be at impaired or removed in the third regions. All features described in combination with the first regions and the second regions also apply to the third regions and the fourth regions. In particular, the size of the second regions and the size of the fourth regions is the same. Additionally or alternatively, the size of the first regions and the size of the fourth regions can be the same.

It is possible that the fourth regions are only arranged above the first regions, whereas the third regions are arranged above the first regions and the second regions. In other words, the first regions are partially covered by the third regions and the fourth regions, whereas the second regions are only covered by the third regions.

By this means, an optoelectronic device can be provided which emits electromagnetic radiation of the first, the second and the third wavelength range, for example, blue, red and green light. In other words, a RGB-triple can be provided.

### BRIEF DESCRIPTION OF THE DRAWINGS

Advantageous embodiments and developments of the method for producing a structured wavelength conversion layer and the optoelectronic device will become apparent from the exemplary embodiments described below in conjunction with the figures.

FIGS. 1A to 1E show steps of a method for producing a structured wavelength conversion layer according to one exemplary embodiment by means of schematic illustrations;

FIGS. 2A to 2F show steps of a method for producing a structured wavelength conversion layer according to another exemplary embodiment by means of schematic illustrations; and

FIG. 3 shows wavelength conversion layers with different compositions.

### DETAILED DESCRIPTION OF ILLUSTRATIVE EMBODIMENTS

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

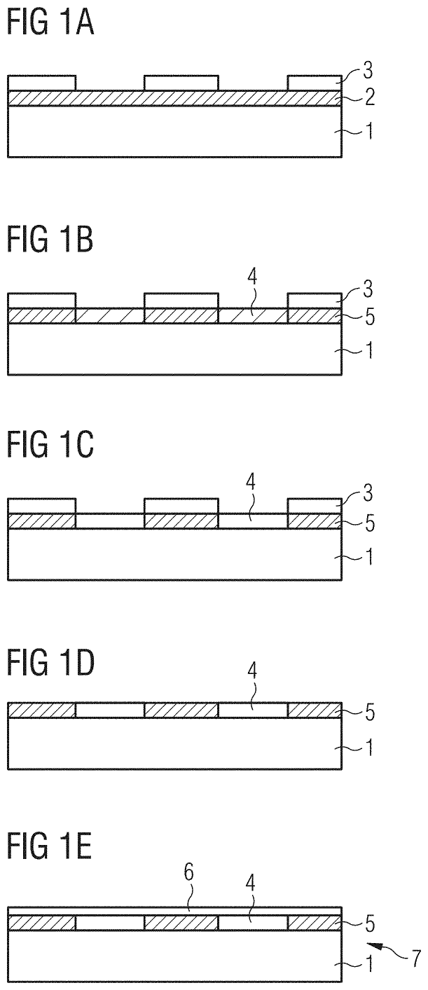

In FIG. 1A a first wavelength conversion layer 2 is provided, for example on a light-emitting semiconductor chip 1. The first wavelength conversion layer 2 comprises quantum dots, in particular CdS quantum dots encapsulated with ZnS. The first wavelength conversion layer 2 is designed to convert electromagnetic radiation of a first wavelength range, for example the blue wavelength range of the visible electromagnetic radiation, into electromagnetic radiation of a second wavelength, for example the red wavelength range of the visible electromagnetic radiation. In other words, the wavelength conversion layer 2 comprises wavelength conversion properties. The light-emitting semiconductor chip 2 is designed to emit electromagnetic radiation of the first wavelength range.

After the first wavelength conversion layer 2 is provided, the first wavelength conversion layer 2 is structured into first regions 4 and second regions 5. This can be achieved by applying a protective mask 3 on the first wavelength conversion layer 2. The protective mask 3 is only applied on the second regions 5. In other words, the first regions 4 are free of the protective mask 3.

The composition of the first wavelength conversion layer 2 is changed by treating the first regions 4 with UV radiation, oxygen and moisture. In other words, aqueous redox chemistry is performed in the first regions aided by irradiation with UV radiation. Due to this treatment, the quantum dots in the first wavelength conversion layer 2 change their composition. For example, CdS is oxidized to CdSO₄.

In the first regions 4, an ability of the quantum dots to absorb the electromagnetic radiation of the first wavelength range is impaired or removed. In other words, the quantum dots stop absorbing electromagnetic radiation of the first wavelength range.

FIG. 1B illustrates a state wherein the wavelength conversion layer 2 shows a reduced ability to absorb the electromagnetic radiation of the first wavelength range in the first regions 4 compared to the second regions 5. The wavelength conversion properties of the wavelength conversion layer 2 are impaired in the first regions 4, but not in the second regions 5.

In FIG. 1C, the wavelength conversion properties of the wavelength conversion layer 2 are removed in the first regions 4. The quantum dots in the first regions 4 do not longer absorb electromagnetic radiation of the first wavelength range. In other words, the first regions 4 are transparent for the electromagnetic radiation of the first wavelength range.

After the composition of the first wavelength conversion layer 2 is changed, the protective mask 3 is removed (FIG. 1D). This reveals the whole 1st wavelength conversion layer 2. As no material is removed during the structuring of the first wavelength conversion layer 2, the first wavelength conversion layer 2 is still continuous. The first wavelength conversion layer 2 has preferably a plane surface. In particular, the moisture used to change the composition of the first wavelength conversion layout 2 in the first regions 4 is removed by heating or under reduced pressure.

As shown in FIG. 1E, a protective layer 6 is applied on the first wavelength conversion layer 2, preferably by ALD. For example, the protective layer 6 comprises Al₂O₃. The protective layer 6 prevents a degradation of the 1st wavelength conversion layer 2 which can be caused by a combination of moisture and electromagnetic radiation. In particular, the protective layer 6 is applied on a surface facing away from the light-emitting semiconductor chip 1. Preferably, the protective layer 6 convers the whole surface of the first wavelength conversion layer 2 facing away from the light-emitting semiconductor chip 1. The protective layer 6 may penetrate into the first wavelength conversion layer 2.

In combination with FIG. 1E also an optoelectronic device 7 is described. The optoelectronic device comprises the light-emitting semiconductor chip 1 and the wavelength conversion layer 2 that is structured into first regions 4 and second regions 5. In the first regions 4, the wavelength conversion layer 2 has an at least impaired ability to convert electromagnetic radiation of the first wavelength range into the second wavelength range. Thus, in the first regions 4, the optoelectronic device 7 emits electromagnetic radiation of the first wavelength range. In the second regions 5 of the first wavelength conversion layer 2, the electromagnetic radiation of the first wavelength range is converted into electromagnetic radiation of the second wavelength range by the quantum dots present in the first wavelength conversion layer 2. The optoelectronic device 7 emits electromagnetic radiation of the first wavelength range and electromagnetic radiation of the second wavelength range in different regions. For example, the optoelectronic device 7 emits electromagnetic radiation in the blue and the red wavelength range of the visible electromagnetic radiation.

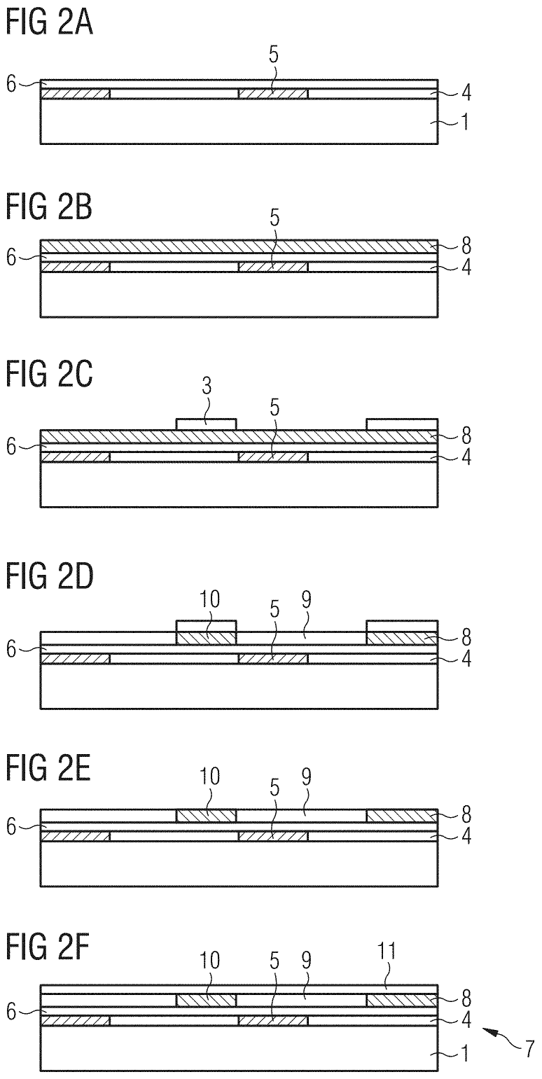

In particular, the first regions 4 and the second regions 5 have the same extent and shape. Alternatively, the second regions 5 may be smaller than the first regions 4. Such a configuration is shown in FIG. 2A.

A second wavelength conversion layer 8 is applied on the first wavelength conversion layer 2, preferably above the protective layer 6 (FIG. 2B). The second wavelength conversion layer 8 comprises wavelength conversion properties such that electromagnetic radiation of the first wavelength range is converted into electromagnetic radiation of a third wavelength range. The third wavelength range can be the green wavelength range of the visible electromagnetic radiation. In particular, the second wavelength conversion layer 8 comprises quantum dots differing in size and/or composition from the quantum dots of the first wavelength conversion layer 2.

For structuring the second wavelength conversion layer 8 into third regions 9 and fourth regions 10, a protective mask 3 is applied on the second wavelength conversion layer, as shown in FIG. 2C. The protective mask 3 covers only the fourth regions 10. The third regions 9 are free of the protective mask 3.

During structuring of the second wavelength conversion layer 8, the composition of the second wavelength conversion layer 8 is changed in the third regions 9 (FIG. 2D). The protective mask 3 prevents the change in composition in the fourth regions 10. Due to the change of composition, the wavelength conversion properties of the second wavelength conversion layer 8 are impaired or removed. For example, during structuring of the second wavelength conversion layer 8, non-aqueous redox chemistry is performed in the third regions 9. No material is removed from the second wavelength conversion layer 8 during structuring. In other words, the second wavelength conversion layer 8 stays mechanically intact.

After the composition of the second wavelength conversion layer 8 is changed in the third regions 9, the protective mask 3 is removed, as shown in FIG. 2E.

Then a further protective layer 11 is applied on the second wavelength conversion layer 8 on the side facing away from the first wavelength conversion layer 2 (FIG. 2F). The further protective layer 11 is designed to protect the second wavelength conversion layer 8 from external influences, like moisture. The further protective layer 11 can be a single layer or are layer stack. For example, the further protective layer 11 comprises Al₂O₃ and/or TiO₂. The further protective layer can penetrate the second wavelength conversion layer 8.

FIG. 2F also shows a further exemplary embodiment of an optoelectronic device 7. The optoelectronic device 7 presently comprises a light-emitting semiconductor chip designed to emit electromagnetic radiation of the first wavelength range as well as a first wavelength conversion layer 2 and a second wavelength conversion layer 8. Compared to the optoelectronic device 7 of FIG. 1E, the present optoelectronic device 7 comprises an additional wavelength conversion layer.

The first wavelength conversion layer 2 shows conversion properties such that electromagnetic radiation of the first wavelength range is converted into electromagnetic radiation of the second wavelength range. The second wavelength conversion layer 8 shows wavelength conversion properties such that electromagnetic radiation of the first wavelength range is converted into electromagnetic radiation of the third wavelength range. Above each wavelength conversion layer a protective layer 6, 11 is arranged. In particular, a protective layer 6 is arranged between the first wavelength conversion layer 2 and the second wavelength conversion layer 8.

The first wavelength conversion layer 2 comprises first regions 4 and second regions 5. The second wavelength conversion layer 8 comprises third regions 9 and fourth regions 10. The second regions 5 are covered by the third regions 9, whereas the first regions 4 are covered by the third regions 9 and the fourth regions 10. In other words, the fourth regions 10 are arranged above the first regions 4 and the third regions 9 are arranged above the first regions 4 and the second regions 10. In particular, the size of the first and the third regions is bigger than the size of the second and the fourth regions.

The optoelectronic device 7 of FIG. 2F is able to emit electromagnetic radiation of the first, the second and the third wavelength range. Areas in which the light-emitting semiconductor chip 1 is covered by the second regions 5 of the first wavelength conversion layer 2 and by the third regions 9 of the second wavelength conversion layer 8 emit electromagnetic radiation of the second wavelength range. Areas in which the light-emitting semiconductor chip 1 is covered by the first regions 4 of the first wavelength conversion layer 2 and by the third regions 9 of the second wavelength conversion layer 8 emit electromagnetic radiation of the first wavelength range. Areas in which the light-emitting semiconductor chip 1 is covered by the first regions 4 of the first wavelength conversion layer 2 and by the fourth regions 10 of the second wavelength conversion layer 8 emit electromagnetic radiation of the third wavelength range.

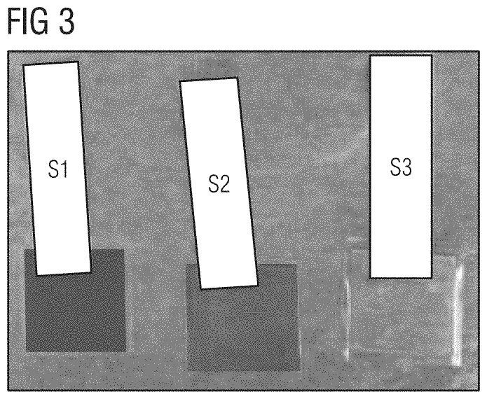

FIG. 3 shows three samples of wavelength conversion layers comprising different compositions. The wavelength conversion layers comprise quantum dots. The samples have been subjected to elevated temperature, moisture and blue light for increasingly longer period from left to right.

In sample S1, most of the quantum dots still have their original composition. Thus, the converting properties of the conversion layer of this sample are unaffected. The quantum dots are still able to convert electromagnetic radiation.

In sample S2, the wavelength converting properties of the wavelength conversion layer is already impaired. This can be explained as the composition of the wavelength conversion layer has changed due to the treatment with temperature, moisture and blue light.

In sample S3, the wavelength converting properties of the wavelength conversion layer are removed. The quantum dots in this particular wavelength conversion layer have completely changed their composition and thus are no longer able to absorb electromagnetic radiation. The wavelength conversion layer is completely transparent.

The features and exemplary embodiments described in connection with the figures can be combined with each other according to further exemplary embodiments, even if not all combinations are explicitly described. Furthermore, the exemplary embodiments described in connection with the figures may have alternative or additional features as described in the general part.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

What is claimed is:

1. A method for producing a structured wavelength conversion layer, the method comprising:
providing a first wavelength conversion layer with wavelength converting properties such that electromagnetic radiation of a first wavelength range is converted into electromagnetic radiation of a second wavelength range; and
structuring of the first wavelength conversion layer into first regions and second regions,
wherein the wavelength converting properties of the first wavelength conversion layer are impaired or removed in the first regions after structuring.

2. The method according to claim 1, wherein the first wavelength conversion layer comprises nanoparticles.

3. The method according to claim 2, wherein the nanoparticles are quantum dots.

4. The method according to claim 3, wherein an ability of the quantum dots to absorb electromagnetic radiation is impaired or removed in the first regions after the structuring of the first wavelength conversion layer.

5. The method according to claim 1, wherein structuring of the first wavelength conversion layer comprises changing a composition of the first wavelength conversion layer in the first regions.

6. The method according to claim 5, wherein structuring of the first wavelength conversion layer comprises applying a protective mask on the first wavelength conversion layer, and patterning the protective mask to generate the first regions and the second regions.

7. The method according to claim 1, wherein structuring of the first wavelength conversion layer comprises changing a composition of the first wavelength conversion layer in the first regions by oxidation processes.

8. The method according to claim 7, further comprising removing a protective mask after the composition of the first wavelength conversion layer is changed in the first regions.

9. The method according to claim 1, wherein structuring of the first wavelength conversion layer comprises treating the first regions with UV radiation.

10. The method according to claim 1, wherein structuring of the first wavelength conversion layer comprises treating the first regions with at least one of the following substances: O₂, O₃, H₂O₂, or N₂O.

11. The method according to claim 1, wherein structuring of the first wavelength conversion layer comprises performing aqueous redox chemistry in the first regions.

12. The method according to claim 1, wherein structuring of the first wavelength conversion layer comprises performing non-aqueous redox chemistry in the first regions.

13. The method according to claim 1, further comprising applying a protective layer on the first wavelength conversion layer after structuring of the first wavelength conversion layer.

14. The method according to claim 13, wherein the protective layer penetrates into the first wavelength conversion layer.

15. The method according to claim 1 further comprising:
providing a second wavelength conversion layer on the first wavelength conversion layer; and
structuring of the second wavelength conversion layer into third regions and fourth regions,
wherein the second wavelength conversion layer has wavelength conversion properties such that the electromagnetic radiation of the first wavelength range is converted into electromagnetic radiation of a third wavelength range, and
wherein the wavelength converting properties of the second wavelength conversion layer are impaired or removed in the third regions after structuring.

16. An optoelectronic device comprising:
a light-emitting semiconductor chip; and
a first wavelength conversion layer with wavelength converting properties such that electromagnetic radiation of a first wavelength range is converted into electromagnetic radiation of a second wavelength range,
wherein the first wavelength conversion layer comprises first regions and second regions,
wherein the wavelength converting properties of the first wavelength conversion layer are impaired or removed in the first regions.

17. The optoelectronic device according to claim 16, wherein the first wavelength conversion layer comprises nanoparticles.

18. The optoelectronic device according to claim 16, wherein the first wavelength range is between 430 nanometers and 490 nanometers, inclusive, and wherein the second wavelength range is between 600 nanometers and 800 nanometers, inclusive.

19. The optoelectronic device according to claim 16, further comprising a protective layer arranged on a side of the first wavelength conversion layer facing away from the light-emitting semiconductor chip.

20. The optoelectronic device according to claim 16, further comprising a second wavelength conversion layer with wavelength converting properties such that electromagnetic radiation of the first wavelength range is converted into electromagnetic radiation of a third wavelength range.
